(19) United States
(12) Patent Application Publication
(10) Pub. No.: US 2007/0292974 A1
(43) Pub. Date: Dec. 20, 2007

(54) Substrate Processing Method and Substrate Processing Apparatus

(75) Inventors: Norikazu Mizuno, Toyama (JP); Taketoshi Sato, Toyama (JP); Masanori Sakai, Toyama (JP); Kazuyuki Okuda, Toyama (JP)

Correspondence Address: BIRCH STEWART KOLASCH & BIRCH, PO BOX 747, FALLS CHURCH, VA, 22040-0747, US

(73) Assignee: Hitachi Kokusai Electric Inc, Tokyo (JP)

(21) Appl. No.: 11/664,282

(22) PCT Filed: Jan. 27, 2006
(86) PCT No.: PCT/JP06/01338

§ 371 Date: Jun. 6, 2007

(30) Foreign Application Priority Data
Feb. 17, 2005 (JP) 2005-040471

(51) Int. Cl. B05C 11/00; H01L 21/00

(52) U.S. Cl. 438/5; 118/699; 257/E21.002

(57) ABSTRACT

Disclosed is a substrate processing method in which a plurality of processing gases are alternately supplied to and exhausted from a processing chamber forming a space in which a substrate or substrates are to be processed to form a desired thin film on the substrate or each of the substrates comprising transferring the substrate or the substrates into the processing chamber, and controlling a supply time of one of the plurality of the processing gases to control an amount of a chemical species which exists in the thin film and the existing amount of which a film stress depends on, thereby controlling the film stress of the thin film.

### TECHNICAL FIELD

The present invention relates to a substrate processing method and a substrate processing apparatus, and more particularly, to a substrate processing method and a substrate processing apparatus for forming a film by an ALD (Atomic Layer Deposition) method which is used when a Si semiconductor device is produced.

### BACKGROUND ART

First, film forming processing using the ALD method will be explained briefly.

According to the ALD method, raw material gases of two kinds (or more) of gases used for forming a film are alternately supplied onto substrates one kind by one kind under given film forming conditions (temperature, time and the like), the gases are adsorbed in one atomic layer unit, and the film is formed utilizing surface reaction.

When a SiN (silicon nitride) film is to be formed for example, in the ALD method, the utilized chemical reaction can form the film of high quality at a low temperature in a range of 300 to 600° C. using DCS (SiH₂Cl₂, dichlorsilane) and NH₃ (ammonia). The plurality kinds of reaction gases are alternately supplied one kind by one kind. The film thickness is controlled based on the number of supply cycles of the reaction gases (for example, if the film forming speed is 1 Å/cycle, the processing is carried out by 20 cycles when a film of 20 Å is formed).

The ALD Method will be explained in more detail based on a vertical type ALD remote plasma apparatus.

To form a silicon nitride film on a Si wafer by the ALD method, NH₃ and DCS (SiH₂Cl₂) are used as a raw material.

Film forming procedure of the silicon nitride film will be shown below.

(1) Wafers are transferred to a quartz boat. At that time, the wafers are supported by support sections made of quartz.

(2) The quartz boat is inserted into a processing chamber having a temperature of 300° C.

(3) If the insertion of the quartz boat is completed, the processing chamber is evacuated, and the temperature is increased to the nitriding process temperature (about 450° C.)

(4) DCS irradiation (three seconds)→N₂ purging (five seconds)→plasma-excitation and NH₃ irradiation (six seconds)→N₂ purging (three seconds) are defined as one cycle, and this cycle is repeated until a predetermined film thickness is obtained.

(5) The reaction gas in the processing chamber is exhausted and the temperature in the processing chamber is lowered to about 300° C. at the same time.

(6) The pressure in the processing chamber is returned to the atmospheric pressure, and the quartz boat is pulled out from the processing chamber.

The reason why the NH₃ irradiation time is six seconds will be explained. If only the film forming time is taken into account as shown in FIG. 7, it is not advantageous to meaninglessly increase the NH₃ irradiation time in terms of throughput. This is because that if the NH₃ irradiation time is seven seconds or longer, the film thickness is not largely varied. Therefore, the throughput is taken into account, and the NH₃ irradiation time before the film thickness was saturated was defined as the standard condition. This is because that this point was not taken into account in the conventional condition in terms of a film stress.

In semiconductor device structures of recent years, a film stress of about 1.5 Gpa is required for moderating distortion, but stress of a film formed through the above-described steps is about 1.2 Gpa and is lower than the target value.

Hence, it is a main object of the present invention to provide a substrate processing method and a substrate processing apparatus capable of controlling the film stress.

### DISCLOSURE OF THE INVENTION

According to one aspect of the present invention, there is provided a substrate processing method in which a plurality of processing gases are alternately supplied to and exhausted from a processing chamber forming a space in which a substrate or substrates are to be processed to form a desired thin film on the substrate or each of the substrates, wherein

a supply time of one of the plurality of the processing gases is controlled to control an amount of a chemical species which exists in the thin film and the existing amount of which a film stress depends on, thereby controlling the film stress of the thin film.

According to another aspect of the present invention, there is provided a film stress control method for controlling a stress of a thin film formed on a substrate or each of substrates by alternately supplying and exhausting a plurality of processing gases to and from a processing chamber forming a space in which the substrate or the substrates are to be processed, wherein

a supply time of one of the plurality of the processing gases is controlled to control an amount of a chemical species which exists in the thin film and the existing amount of which a film stress depends on, thereby controlling the film stress of the thin film.

According to still another aspect of the present invention, there is provided a film stress control method for controlling a stress of a thin film formed on a substrate or each of substrates by alternately supplying and exhausting a plurality of processing gases to and from a processing chamber forming a space in which the substrate or the substrates are processed, wherein

a supply time of one of the plurality of the processing gases is controlled to control a film stress of the thin film.

According to still another aspect of the present invention, there is provided a substrate processing apparatus, comprising:

a processing chamber forming a space in which a substrate or substrates are processed,

a gas supply section to supply a plurality of processing gases into the processing chamber,

an exhausting section to exhaust an atmosphere in the processing chamber, and

a control section capable of arbitrarily setting supply times of the plurality of the processing gases, wherein

the plurality of the processing gases are alternately supplied to and exhausted from the processing chamber to form a desired thin film on the substrate or each of the substrates, and

the control section sets and controls a supply time of one of the plurality of the processing gases to control an amount of a chemical species which exists in the thin film and an existing amount of which a film stress depends on, thereby controlling the film stress of the thin film.

### BRIEF DESCRIPTION OF DRAWINGS

FIG. 1 is a diagram for explaining a reaction mechanism of an ALD.

FIG. 2 is a diagram for explaining an ALD growing cycle of a preferred embodiment of the present invention.

FIG. 3 is a diagram showing a relation between NH₃ irradiation time, concentration of Hand concentration of Cl.

FIG. 4 is a diagram showing a relation between NH₃ irradiation time and film stress.

FIG. 5 is a diagram showing a relation between DCS irradiation time and film stress.

FIG. 6 is a diagram showing temperature dependence of the film stress.

FIG. 7 is a diagram showing a relation between the NH₃ irradiation time and a thickness of a formed film.

FIG. 8 is a schematic vertical sectional view for explaining a vertical type substrate processing furnace of a substrate processing apparatus according to preferred embodiments of the present invention.

FIG. 9 is a schematic cross sectional view for explaining a vertical type substrate processing furnace of a substrate processing apparatus according to a preferred embodiments of the present invention.

FIG. 10 is a schematic diagrammatic perspective view for explaining the substrate processing apparatus of the preferred embodiments of the present invention.

FIG. 11 is a schematic vertical view for explaining the substrate processing apparatus of the preferred embodiments of the present invention.

### PREFERRED EMBODIMENTS FOR CARRYING OUT THE INVENTION

Preferred embodiments of the present invention will be explained next.

According to the preferred embodiments of the present invention, film stress of a nitride film formed by controlling supply time of NH₃ in a silicon nitride film (ALD nitride film) forming process by an ALD method is controlled.

In the preferred embodiments of the present invention, the film stress is controlled by controlling concentrations of Cl and H in the silicon nitride film formed by the ALD method.

Next, the preferred embodiments of the present invention will be explained in more detail.

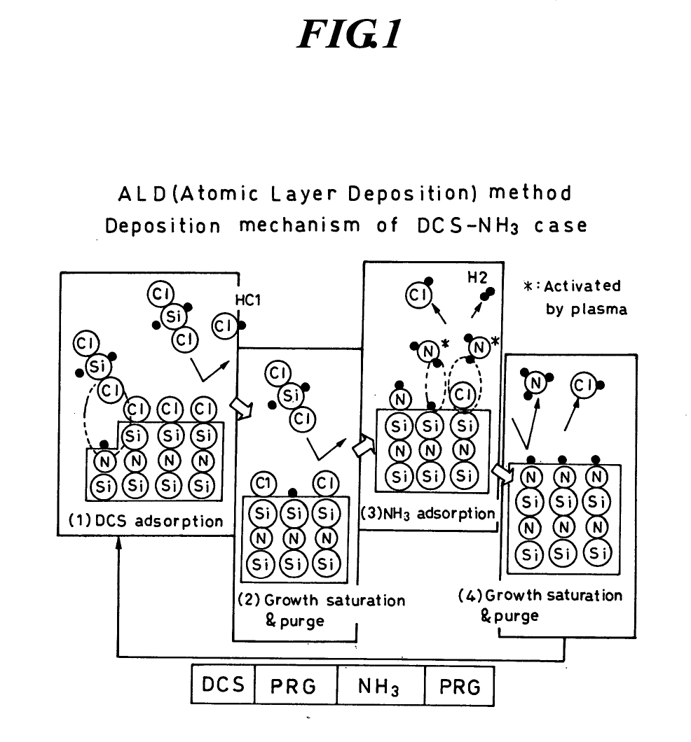

First, a reaction mechanism of the ALD will be explained with reference to FIG. 1.

(1) First, Si and Cl are adsorbed on a surface by DCS irradiation (supply) (DCS).

(2) Next, N₂ purge is carried out for preventing DCS and NH₃ from being mixed with each other (PRG).

(3) Next, irradiation (supply) of excited NH₃ is carried out, resulting in that Cl adsorbed in (1) is separated as HCl, and N and H are adsorbed (NH₃).

(4) Next, N₂ purge is carried out for preventing NH₃ and DCS from being mixed with each other (PRG).

A cycle of (1) to (4) is repeated until a film thickness reaches a predetermined value.

Since the reaction proceeds in the above-described manner, impurities of H and Cl in addition to Si and N which are main components of the ALD silicon nitride film are taken into the film.

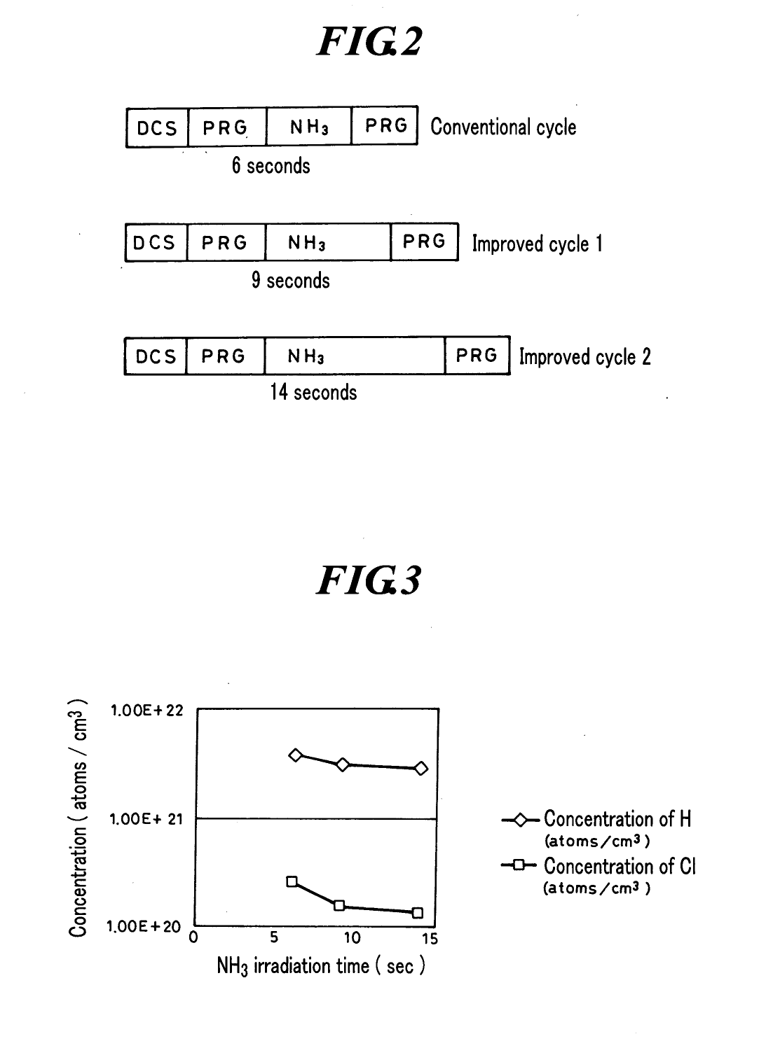

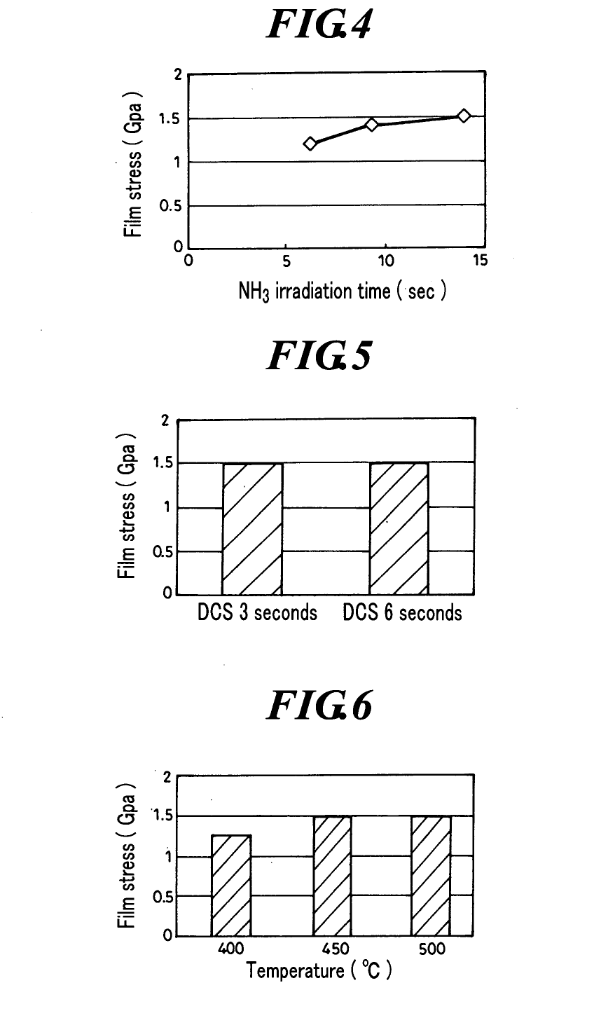

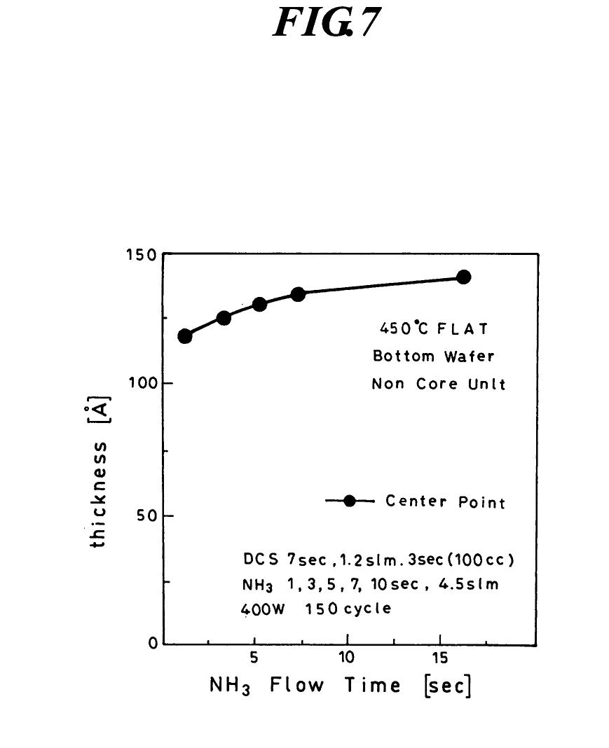

To control the film stress, an experiment for changing the irradiation time of excited NH₃ was carried out. FIG. 2 shows a conventional cycle and improved cycles. The NH₃ irradiation time was changed to 6 seconds, 9 seconds and 14 seconds. FIG. 4 shows a result of the film stress at those times. It is found that if the excited NH₃ irradiation time is increased, the film stress is increased.

FIG. 3 shows a result of measurement of concentration of H (hydrogen) and Cl (chlorine) in a film carried out using SIMS. As the NH₃ irradiation time is increased, both H and Cl are reduced. Although Cl is taken into a surface from DCS which is a raw material of Cl, Cl is separated from the surface in a process of irradiation of NH₃. Therefore, as the NH₃ irradiation time is longer, the separating effect of Cl is higher, and concentration of Cl in the film is reduced.

Thus, it can be found that film stress depends on concentration of impurities such as H and Cl in a film.

That is, the film stress can be controlled by controlling concentrations of H and Cl, i.e., by controlling the NH₃ irradiation time.

The dependence of film stress on the irradiation time of DCS which is one of the gases was researched. FIG. 5 shows a result of the research and it is found that stress is not varied depending upon the DCS irradiation time. Thus, film stress is largely influenced by NH₃ irradiation time.

FIG. 6 shows the dependence. It is found that as the temperature is higher, the film stress becomes higher and the concentration of Cl is lower. If only the film stress is taken into account, a process condition of higher temperature is advantageous, but the process temperature cannot be changed in many cases. This is because that if the temperature is increased, demerits that NiSi (nickel siliside) is deteriorated and impurities are diffused again are generated. Therefore, if the NH₃ irradiation time is increased at a low temperature, there is a merit that the film stress is increased and it is possible to restrain NiSi from being deteriorated and to restrain impurities from being diffused again. Here, NiSi is a material used for an electrode of a logic semiconductor device. Conventionally, CoSi (cobalt siliside) is a general material for electrodes, but it is desired to lower resistance of the electrode, and NiSi having a low resistance has been employed in recent years. If the resistance is lowered, the switching speed has been increased, and an integration degree can be increased, and this is an important factor.

Next, one example of a substrate processing apparatus used in the preferred embodiments of the present invention will be explained with reference to the drawings.

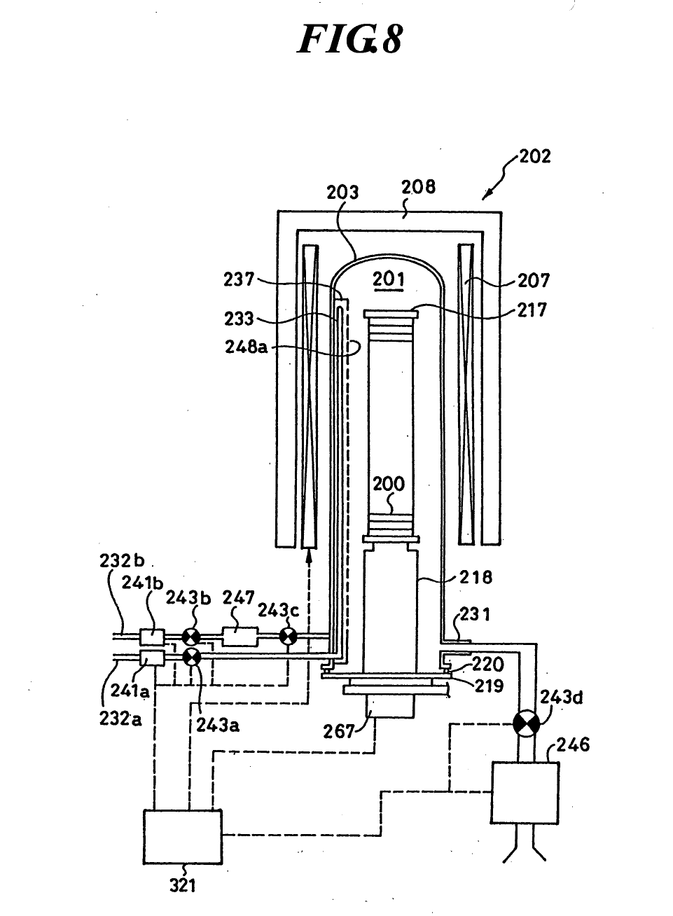

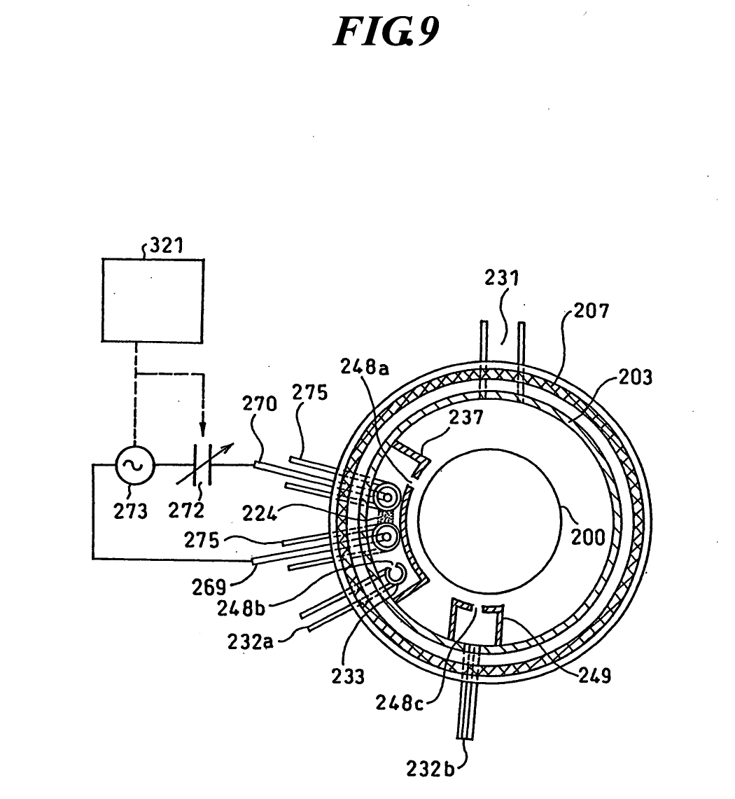

FIG. 8 is an explanatory schematic diagram showing a structure of a vertical type substrate processing furnace of the present embodiments, and shows a processing furnace portion in vertical cross section. FIG. 9 is an explanatory schematic diagram showing a structure of the vertical type substrate processing furnace of the embodiments, and shows the processing furnace portion in transverse cross section.

A quartz reaction tube 203 as a reaction container is provided inside of a heater 207 which is heating means. The reaction tube 203 processes wafers 200 as substrates. A lower end opening of the reaction tube 203 is air-tightly closed by a seal cap 219 which is a lid through an O-ring 220 as an airtight member. A thermal insulation member 208 is provided outside of the reaction tube 203 and the heater 207. The thermal insulation member 208 covers an upper end of the heater 207. At least the heater 207, the thermal insulation member 208, the reaction tube 203 and the seal cap 219 form a processing furnace 202. The reaction tube 203, the seal cap 219 and a later-described buffer chamber 237 formed in the reaction tube 203 form a processing chamber 201. A boat 217 which is substrate-holding means stands on the seal cap 219 through a quartz cap 218. The quartz cap 218 functions as a holding body which holds the boat 217. The boat 217 is inserted into the processing furnace 202. The plurality of wafers 200 to be batch processed are stacked in the boat 217 in the vertical direction in many layers in an axial direction of the tube in their horizontal attitudes. The heater 207 heats the wafers 200 inserted into the processing furnace 202 to a predetermined temperature.

The processing furnace 202 is provided with two gas supply tubes 232a and 232b as supply tubes for supplying a plurality kinds (two kinds, in this embodiment) of gases to the processing furnace 202. Reaction gas is supplied from the gas supply tube 232a to the processing chamber 201 through a mass flow controller 241a which is flow rate control means, and a valve 243a which is an open/close valve, and the buffer chamber 237 formed in the reaction tube 203. Further, reaction gas is supplied to the processing chamber 201 from the gas supply tube 232b through a mass flow controller 241b which is flow rate control means, a valve 243b which is an open/close valve, the gas holder 247, a valve 243c which is an open/close valve, and a later-described gas supply section 249.

Tube heaters (not shown) capable of heating to about 120° C. are mounted on the two gas supply tubes 232a and 232b for preventing NH₄Cl which is a reaction by-product from adhering to the tubes.

The processing chamber 201 is connected to a vacuum pump 246 which is exhausting means through a valve 243d by a gas exhaust tube 231 which is an exhaust tube through which gas is exhausted so that the processing chamber 201 is evacuated. The valve 243d is an open/close valve, and the processing chamber 201 can be evacuated and the evacuation can be stopped by opening and closing the valve 243d. If the opening of the valve is adjusted, the pressure in the processing chamber 201 can be adjusted.

A buffer chamber 237 which is a gas dispersing space is provided in an arc space between the reaction tube 203 constituting the processing chamber 201 and the wafers 200. The buffer chamber 237 is provided along the stacking direction of the wafers 200 and along an inner wall of the reaction tube 203 higher than a lower portion of the reaction tube 203. Gas supply holes 248a which are supply holes through which gas is supplied are formed in an inner wall of the buffer chamber 237 adjacent to the wafers 200. The gas supply holes 248a are opened toward the center of the reaction tube 203. The gas supply holes 248a have the same opening areas over a predetermined length from a lower portion to an upper portion along the stacking direction of the wafers 200, and pitches between the gas supply holes 248a are equal to each other.

A nozzle 233 is disposed near an end of the buffer chamber 237 on the opposite side from an end of the buffer chamber 237 where the gas supply holes 248a are provided. The nozzle 233 is disposed along the stacking direction of the wafers 200 from the lower portion to the upper portion of the reaction tube 203. The nozzle 233 is provided with a plurality of gas supply holes 248b which are supply holes through which gas is supplied. The plurality of gas supply holes 248b are disposed along the stacking direction of the wafers 200 over the same predetermined length as that of the gas supply holes 248a. The plurality of gas supply holes 248b and the plurality of gas supply holes 248a are disposed at corresponding locations, respectively.

When a pressure difference between the buffer chamber 237 and the processing furnace 202 is small, it is preferable that the opening areas of the gas supply holes 248b are equal to each other from the upstream side to the downstream side and the opening pitches are the same, but when the pressure difference is large, it is preferable that the opening area is increased from the upstream side toward the downstream side or the opening pitches are reduced.

By adjusting the opening areas or opening pitches of the gas supply holes 248b from the upstream side toward the downstream side, gas is ejected with a substantially uniform flow rate although the velocities of flows of gases through the respective gas supply holes 248b are different from each other. The gas ejected from the gas supply holes 248b is ejected into the buffer chamber 237 and is once introduced, and the velocities of flows of gases can be equalized.

That is, in the buffer chamber 237, the particle velocity of gas ejected from each gas supply hole 248b is moderated in the buffer chamber 237 and then, the gas is ejected into the processing chamber 201 from the gas supply hole 248a. During that time, the gas ejected from each gas supply hole 248b becomes gas having equal flow rate and velocity of flow when the gas is ejected from the gas supply hole 248a.

A rod-like electrode 269 and a rod-like electrode 270 having thin and long structures are disposed in the buffer chamber 237 such that these electrodes are protected by electrode protection tubes 275 which are protection tubes for protecting these electrodes from upper portions to lower portions. One of the rod-like electrode 269 and the rod-like electrode 270 is connected to the high frequency power supply 273 through the matching device 272, and the other electrode is connected to the ground which is a reference electric potential. As a result, plasma is produced in a plasma producing region 224 between the rod-like electrode 269 and the rod-like electrode 270.

These electrode protection tubes 275 have such structures that the rod-like electrode 269 and the rod-like electrode 270 can be inserted into the buffer chamber 237 in a state where the electrodes are isolated from the atmosphere in the buffer chamber 237. If the inside of the electrode protection tubes 275 is the same as the atmosphere (outside air), the rod-like electrode 269 and the rod-like electrode 270 respectively inserted into the electrode protection tubes 275 are heated by the heater 207 and oxidized. Hence, there is provided an inert gas purge mechanism which charges inert gas such as nitrogen into the electrode protection tubes 275 or replaces an atmosphere in the electrode protection tubes 275 by the inert gas, thereby sufficiently reducing the concentration of oxygen, and which prevents the rod-like electrode 269 and the rod-like electrode 270 from being oxidized.

A gas supply section 249 is formed in an inner wall separated from the position of the gas supply holes 248a by about 120° along an inner periphery of the reaction tube 203. The gas supply section 249 is a supply section which shares the gas supply kinds with the buffer chamber 237 when the plurality kinds of gases are alternately supplied to the wafers 200 one kind by one kind when films are formed by the ALD method.

Like the buffer chamber 237, the gas supply section 249 also has gas supply holes 248c which are supply holes through which gas is supplied to positions adjacent to the wafers at the same pitch, and a gas supply tube 232b is connected to a lower portion of the gas supply section 249.

When a pressure difference between the buffer chamber 237 and the processing chamber 201 is small, it is preferable that the opening areas of the gas supply holes 248c are equal to each other from the upstream side to the downstream side and the opening pitches are the same, but when the pressure difference is large, it is preferable that the opening area is increased from the upstream side toward the downstream side or the opening pitches are reduced.

The boat 217 is provided at a central portion in the reaction tube 203, and the plurality of wafers 200 are placed in many layers at equal distances from one another in the vertical direction. The boat 217 can be brought into and out from the reaction tube 203 by a boat elevator mechanism (not shown). To enhance the uniformity of the processing, a boat rotating mechanism 267 which is rotating means for rotating the boat 217 is provided. By rotating the boat rotating mechanism 267, the boat 217 held by the quartz cap 218 is rotated.

A controller 321 which is control means is connected to the mass flow controllers 241a and 241b, the valves 243a, 243b, 243c and 243d, the heater 207, the vacuum pump 246, the boat rotating mechanism 267, the boat elevator 121, the high frequency power supply 273 and the matching device 272. The controller 321 adjusts flowrates of the mass flow controllers 241a and 241b, opens and closes valves 243a, 243b and 243c, opens and closes the valve 243d, adjusts a pressure of the valve 243d, adjusts the temperature of the heater 207, actuates and stops the vacuum pump 246, adjusts rotation of the boat rotating mechanism 267, controls a vertical motion of the boat elevator 121, controls supply of electric power of the high frequency power supply 273, and controls impedance by the matching device 272. By controlling the opening and closing motions of the valves 243a, 243b, 243c and 243d by the controller 321, the supply time of processing gas supplied from the two gas supply tubes 232a and 232b is arbitrarily set.

Next, an example of the film forming operation by the ALD method will be explained based on a case wherein SiN films are formed using DCS gas and NH₃ gas.

First, wafers 200 on which films are to be formed are mounted on the boat 217, and the boat 217 is brought into the processing furnace 202. Then, the following steps 4 to 7 are repeatedly carried out in sequence.

[Step 1]

First, the valve 243d of the gas exhaust tube 231 is opened, the processing chamber 201 is exhausted by the vacuum pump 246 to 20 Pa or lower.

The upstream side valve 243b of the gas supply tube 232b is opened and the downstream side valve 243c is closed so that DCS flows. With this, DCS is stored in the gas holder 247 provided between the valves 243b and 243c. If a predetermined amount of DCS having a predetermined pressure (e.g., 20,000 Pa or higher) is stored in the gas holder 247, the upstream side valve 243b is closed, and DCS is sealed in the gas holder 247. The apparatus is constituted such that the conductance between the gas holder 247 and the processing chamber 201 becomes 1.5×10⁻³ m³/s or higher. If a ratio between a capacity of the reaction tube 203 and a capacity of the gas holder 247 is considered, when the capacity of the reaction tube 203 is 100 l (liters), it is preferable that the capacity of the gas holder 247 is in a range of 100 to 300 cc, and it is preferable that as the capacity ratio, the capacity of the gas holder 247 is 1/1,000 to 3/1,000 times of the capacity of the reaction chamber.

[Step 2]

If the exhausting operation of the processing chamber 201 is completed, the valve 243c of the gas exhaust tube 231 is closed to stop the exhausting operation. The valve 243c located downstream of the gas supply tube 232b is opened. With this, DCS stored in the gas holder 247 is supplied to the processing chamber 201 at a dash. At that time, since the valve 243d of the gas exhaust tube 231 is closed, the pressure in the processing chamber 201 is increased abruptly to about 931 Pa (7 Torr). Time during which DCS was supplied is set to two to four seconds, and time during which the wafers were exposed to the increased pressure atmosphere was set to two to four seconds, and total time was set to six seconds. The temperature of the wafers at that time is 450° C.

[Step 3]

Then, the valve 243c is closed and the valve 243d is opened, the processing chamber 201 is evacuated, and residual DCS gas is exhausted. At that time, if inert gas such as N₂ is supplied to the processing chamber 201, the effect for exhausting the residual gas after it contributed to the formation of DCS films from the processing chamber 201 is enhanced. The valve 243b is opened and supply of DCS into the gas holder 247 is started.

[Step 4]

In step 3, the valve 243a provided in the gas supply tube 232a and the valve 243d provided in the gas exhaust tube 231 are both opened, NH₃ gas whose flow rate is adjusted by the mass flow controller 243a is sent from the gas supply tube 232a and ejected into the buffer chamber 237 from the gas supply holes 248b of the nozzle 233, high frequency electric power is applied between the rod-like electrode 269 and the rod-like electrode 270 from the high frequency power supply 273 through the matching device 272 to plasma-excite NH₃, and the excited gas is supplied to the processing chamber 201 as active species and in this state, gas is exhausted from the gas exhaust tube 231. When flowing the NH₃ gas by plasma-exciting the NH₃ gas as active species, the valve 243d is appropriately adjusted, and a pressure in the processing chamber 201 is adjusted to 10 to 100 Pa. A supply flow rate of NH₃ controlled by the mass flow controller 241a is in a range of 1,000 to 10,000 sccm. Time during which the wafers 200 are exposed to the active species obtained by plasma-exciting NH₃ is longer than that of the conventional technique (6 seconds or longer), and is 9 or 14 seconds. The temperature of the heater 207 at that time is set such that the temperature of the wafer becomes 450° C. Since the reaction temperature of NH₃ is high, the NH₃ does not react at the temperature of the wafer. Therefore, NH₃ is fed as active species by plasma-exciting the same. Therefore, the wafers can be kept in the set low temperature range.

When NH₃ is plasma-excited and fed as active species, the valve 243b located upstream of the gas supply tube 232b is opened and the valve 243c located downstream is closed so that DCS flows also. With this, DCS is stored in the gas holder 247 provided between the valves 243b and 243c. Gas flowing into the processing chamber 201 is the active species obtained by plasma-exciting the NH₃, and DCS does not exist. Therefore, NH₃, which has been plasma-excited and which becomes the active species, surface-reacts with DCS, which has been adsorbed on the wafer 200, without generating a vapor-phase reaction, and a SiN film is formed on the wafer 200.

The time during which the wafer 200 is exposed to the active species obtained by plasma-exciting NH₃ is longer than that of the conventional technique (6 seconds or longer) and is 9 or 14 seconds. Therefore, even after the thickness of the film formed by flowing NH₃ is saturated, active species obtained by plasma-exciting NH₃ continuously flows. The film stress of the formed film is also increased.

[Step 5]

In step 5, the valve 243a of the gas supply tube 232a is closed to stop the supply of NH₃, but supply to the gas holder 247 is continued. If a predetermined amount of DCS having a predetermined pressure is stored in the gas holder 247, the upstream valve 243b is also closed, and DCS is confined in the gas holder 247. The valve 243d of the gas exhaust tube 231 is held opened, the processing chamber 201 is evacuated by the vacuum pump 246 to 20 Pa or lower, and remaining NH₃ is exhausted from the processing chamber 201. At that time, if inert gas such as N₂ is supplied to the processing chamber 201, the effect for exhausting the residual NH₃ is further enhanced. The DCS is stored in the gas holder 247 such that the pressure therein becomes 20,000 Pa or higher.

[Step 6]

In step 6, if the exhausting operation of the processing chamber 201 is completed, the valve 243c of the gas exhaust tube 231 is closed to stop the exhausting operation. The valve 243c located downstream of the gas supply tube 232b is opened. With this, DCS stored in the gas holder 247 is supplied to the processing chamber 201 at a dash. At that time, since the valve 243d of the gas exhaust tube 231 is closed, the pressure in the processing chamber 201 is increased abruptly to about 931 Pa (7 Torr). Time during which DCS was supplied is set to two to four seconds, and time during which the wafers were exposed to the increased pressure atmosphere was set to two to four seconds, and total time was set to six seconds. The temperature of the wafers at that time is the same as the temperature when NH₃ is supplied, i.e., 450° C. By supplying DCS, DCS is adsorbed on the foundation film.

[Step 7]

In step 7, the valve 243c is closed and the valve 243d is opened, and the processing chamber 201 is evacuated, and residual DCS gas is exhausted. At that time, if inert gas such as N₂ is supplied to the processing chamber 201, the effect for exhausting the residual gas after it contributed to the formation of DCS films from the processing chamber 201 is enhanced. The valve 243b is opened and supply of DCS into the gas holder 247 is started.

The above steps 4 to 7 are defined as one cycle, and this cycle is repeated a plurality of times, and SiN films each having a predetermined thickness are formed on the wafers.

In the ALD apparatus, gas is adsorbed on a foundation film surface. The adsorption amount of gas is proportional to exposure time of gas. Therefore, in order to adsorb a desired amount of gas for a short time, it is necessary to increase the pressure of gas for a short time. In the embodiment, since DCS stored in the gas holder 247 is momentarily supplied in a state where the valve 243d is closed, the pressure of DCS in the processing chamber 201 can be increased abruptly, and a desired amount of gas can be adsorbed momentarily.

In the embodiment, NH₃ gas is plasma-excited and supplied as active species and the processing chamber 201 is evacuated while DCS is stored in the gas holder 247. Such operations are necessary steps in the ALD method. Therefore, a special step for storing the DCS is not required. Further, the processing chamber 201 is evacuated and NH₃ gas is removed and then, DCS flows. Therefore, these gases do not react when they are sent toward the wafers 200. The supplied DCS can effectively react only with NH₃ which is adsorbed on the wafers 200.

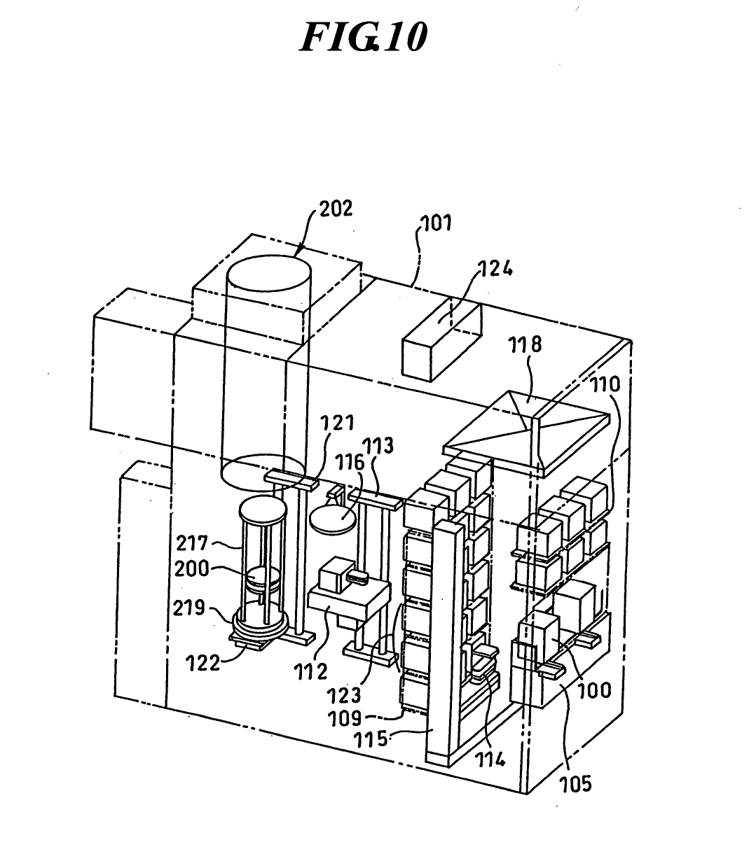

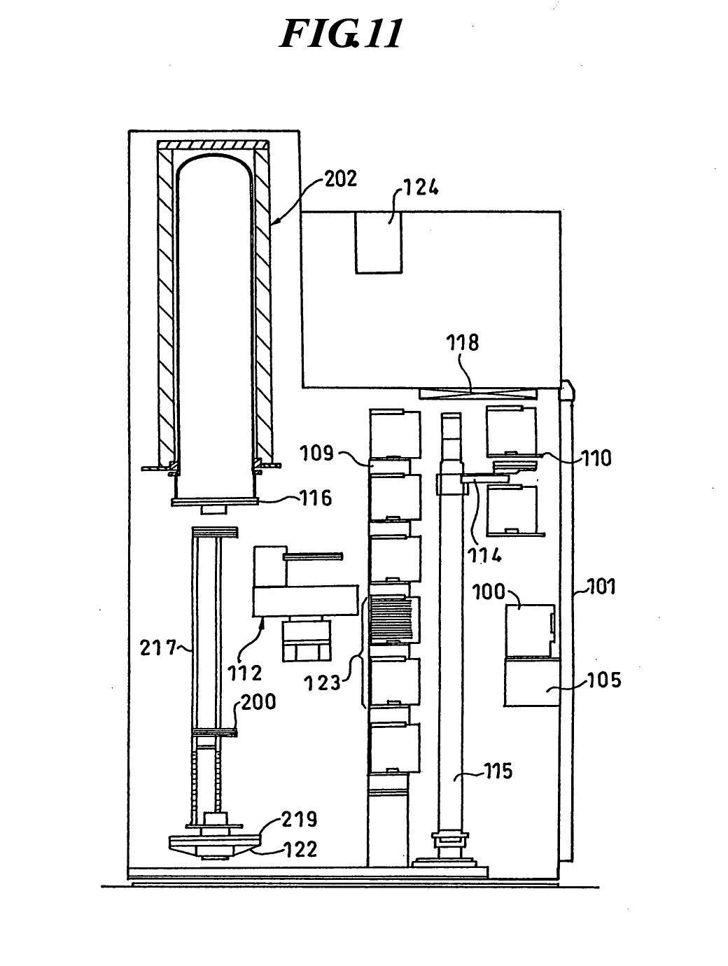

Next, an outline of the substrate processing apparatus of the preferred embodiments will be explained with reference to FIGS. 10 and 11.

A cassette stage 105 as a holder delivery member which delivers cassettes 100 as substrate accommodating containers to and from an external transfer device (not shown) is provided on a front side in a case 101. A cassette elevator 115 as elevator means is provided behind the cassette stage 105. A cassette transfer device 114 as transfer means is mounted on the cassette elevator 115. Cassette shelves 109 as mounting means of the cassettes 100 are provided behind the cassette elevator 115. Auxiliary cassette shelves 110 are also provided above the cassette stage 105. A clean unit 118 is provided above the auxiliary cassette shelves 110 and clean air flows through the case 101.

The processing furnace 202 is provided on the rear side and at an upper portion in the case 101. The boat elevator 121 as elevator means is provided below the processing furnace 202. The boat elevator 121 vertically brings the boat 217 as the substrate holding means into and from the processing furnace 202. The boat 217 holds the wafers 200 as substrates in many layers in their horizontal attitudes. The seal cap 219 as a lid is mounted on a tip end of the elevator member 122 which is mounted on the boat elevator 121, and the seal cap 219 vertically supports the boat 217. A transfer elevator 113 as elevator means is provided between the boat elevator 121 and the cassette shelf 109, and a wafer transfer device 112 as transfer means is mounted on the transfer elevator 113. A furnace opening shutter 116 as closing means which air-tightly closes a lower side of the processing furnace 202 is provided beside the boat elevator 121. The furnace opening shutter 116 has an opening/closing mechanism.

The cassette 100 in which wafers 200 are loaded is transferred onto the cassette stage 105 from an external transfer device (not shown) in such an attitude that the wafers 200 are oriented upward, and the cassette 100 is rotated by the cassette stage 105 by 90° such that the wafers 200 are oriented horizontally. The cassette 100 is transferred from the cassette stage 105 onto the cassette shelf 109 or the auxiliary cassette shelf 110 by a combination of vertical and lateral motions of the cassette elevator 115, and advancing and retreating motions and a rotation motion of the cassette transfer device 114.

Some of the cassette shelves 109 are transfer shelves 123 in which cassettes 100 to be transferred by the wafer transfer device 112 are accommodated. Cassettes 100 to which the wafers 200 are transferred are transferred to the transfer shelf 123 by the cassette elevator 115 and the cassette transfer device 114.

If the cassette 100 is transferred to the transfer shelf 123, the transfer shelf 123 transfers the wafers 200 to the lowered boat 217 by a combination of advancing and retreating motions and a rotation motion of the wafer transfer device 112, and a vertical motion of the transfer elevator 113.

If a predetermined number of wafers 200 are transferred to the boat 217, the boat 217 is inserted into the processing furnace 202 by the boat elevator 121, and the seal cap 219 air-tightly closes the processing furnace 202. The wafers 200 are heated in the air-tightly closed processing furnace 202, processing gas is supplied into the processing furnace 202, and the wafers 200 are processed.

If the processing of the wafers 200 is completed, the wafers 200 are transferred to the cassette 100 of the transfer shelf 123 from the boat 217, the cassette 100 is transferred to the cassette stage 105 from the transfer shelf 123 by the cassette transfer device 114, and is transferred out from the case 101 by the external transfer device (not shown) through the reversed procedure. When the boat 217 is in its lowered state, the furnace opening shutter 116 air-tightly closes the lower surface of the processing furnace 202 to prevent outside air from being drawn into the processing furnace 202.

The transfer motions of the cassette transfer device 114 and the like are controlled by transfer control means 124.

The entire disclosure of Japanese Patent Application No. 2005-40471 filed on Feb. 17, 2005 including specification, claims, drawings and abstract are incorporated herein by reference in its entirety, as far as the national law of the countries designated or selected in the international application permits the incorporation by reference.

Although various exemplary embodiments have been shown and described, the invention is not limited to the embodiments shown. Therefore, the scope of the invention is intended to be limited solely by the scope of the claims that follow.

### INDUSTRIAL APPLICABILITY

As described above, according to an embodiment of the present invention, the film stress can be controlled.

As a result, the present invention is particularly applicable to a substrate processing method and a substrate processing apparatus for forming a film by an ALD method which is used when a Si semiconductor device is produced.

What is claimed is:

1. A substrate processing method in which a plurality of processing gases are alternately supplied to and exhausted from a processing chamber forming a space in which a substrate or substrates are to be processed to form a desired thin film on the substrate or each of the substrates, comprising:
transferring the substrate or the substrates into the processing chamber; and
controlling a supply time of one of the plurality of the processing gases to control an amount of a chemical species which exists in the thin film and the existing amount of which a film stress depends on, thereby controlling the film stress of the thin film.

9. A film stress control method for controlling a stress of a thin film formed on a substrate or each of substrates by alternately supplying and exhausting a plurality of processing gases to and from a processing chamber forming a space in which the substrate or the substrates are to be processed, comprising:
transferring the substrate or the substrates into the processing chamber; and
controlling a supply time of one of the plurality of the processing gases to control an amount of a chemical species which exists in the thin film and the existing amount of which a film stress depends on, thereby controlling the film stress of the thin film.
